(19) United States
(12) Patent Application Publication
(10) Pub. No.: US 2025/0386488 A1
(43) Pub. Date: Dec. 18, 2025

(54) INTEGRATED CIRCUIT MEMORY DEVICES HAVING HIGH DEGREES OF VERTICAL INTEGRATION AND IMPROVED ELECTRICAL CHARACTERISTICS

(71) Applicant: Samsung Electronics Co., Ltd., Suwon-si (KR)

(72) Inventors: Taegyu Kang, Suwon-si (KR); Jinwoo Han, Suwon-si (KR)

(21) Appl. No.: 19/025,111

(22) Filed: Jan. 16, 2025

(30) Foreign Application Priority Data
Jun. 17, 2024 (KR) 10-2024-0078471

(51) Int. Cl. H10B 12/00

(52) U.S. Cl. CPC H10B 12/488; H10B 12/315; H10B 12/482; H10B 12/50

(57) ABSTRACT

An integrated circuit memory device includes a semiconductor pattern including a first source/drain impurity region, a second source/drain impurity region and a channel region extending in series between the first and second source/drain impurity regions. A dual work function word line is provided, which includes a first material having a first work function on a first portion of the channel region, and a second material having a second work function greater than the first work function on at least a second portion of the channel region. A bit line is electrically connected to the first source/drain impurity region, and a first node of a memory cell storage device is electrically connected to the second source/drain impurity region. The first and second source/drain impurity regions may be net P-type impurity regions.

### REFERENCE TO PRIORITY APPLICATION

This application claims priority under 35 U.S.C. § 119 to Korean Patent Application No. 10-2024-0078471, filed Jun. 17, 2024, the disclosure of which is hereby incorporated herein by reference.

### BACKGROUND

The inventive concept relates to integrated circuit memory devices and, more particularly, to highly vertically-integrated (e.g., 3D) memory devices.

As electronic products are required to be miniaturized, multifunctional, and highly efficient, high-capacity semiconductor memory devices are required, and increased integration density is needed to provide higher capacity semiconductor memory devices. A three-dimensional (3D) semiconductor memory device, which utilizes a plurality of memory cells stacked on a substrate in a vertical direction to increase a memory capacity, has been proposed.

### SUMMARY

The inventive concept provides a three-dimensional (3D) semiconductor memory device, which includes a cell transistor including a p-type field-effect transistor (pFET).

The technical objectives of the inventive concept are not limited to the above disclosure; other objectives may become apparent to those of ordinary skill in the art based on the following descriptions.

According to an aspect of the inventive concept, there is provided a semiconductor memory device including a first substrate, semiconductor patterns extending in a first lateral direction on the first substrate, the semiconductor patterns being apart from each other in a second lateral direction and a vertical direction, each semiconductor pattern including a channel region, a first impurity region, and a second impurity region, and the first impurity region and the second impurity region being arranged in the first lateral direction with the channel region therebetween, wherein the second lateral direction intersects with the first lateral direction, a word line surrounding the semiconductor pattern and extending in the second lateral direction, a bit line electrically connected to the first impurity region of the semiconductor pattern, the bit line extending in the vertical direction, and a cell capacitor electrically connected to the second impurity region of the semiconductor pattern, wherein the first impurity region and the second impurity region of the semiconductor pattern have P-type conductivity.

According to another aspect of the inventive concept, there is provided a semiconductor memory device including a first substrate, semiconductor patterns extending in a first lateral direction on the first substrate, the semiconductor patterns being apart from each other in a second lateral direction and a vertical direction, each semiconductor pattern including a channel region, a first impurity region, and a second impurity region, and the first impurity region and the second impurity region being arranged in the first lateral direction with the channel region therebetween, wherein the second lateral direction intersects with the first lateral direction, a word line surrounding the semiconductor pattern and extending in the second lateral direction, a bit line electrically connected to the first impurity region of the semiconductor pattern, the bit line extending in the vertical direction, and a cell capacitor electrically connected to the second impurity region of the semiconductor pattern. The semiconductor pattern includes a seed layer extending in the first lateral direction, and an epitaxial layer surrounding the seed layer and extending in the first lateral direction, wherein the first impurity region and the second impurity region of the seed layer include silicon germanium (SiGe) doped with P-type impurities or silicon (Si) doped with P-type impurities, the first impurity region and the second impurity region of the epitaxial layer include a SiGe epitaxial layer doped with P-type impurities.

According to another aspect of the inventive concept, there is provided a semiconductor memory device including a first stack structure including a memory cell area, the memory cell area including a plurality of memory cells and a plurality of cell capacitors, which are arranged three-dimensionally, and a second stack structure on the first stack structure, the second stack structure including a peripheral circuit area vertically overlapping the plurality of memory cells, and the peripheral circuit area being electrically connected to the plurality of memory cells, wherein the first stack structure includes a first substrate, semiconductor patterns extending in a first lateral direction on the first substrate, the semiconductor patterns being apart from each other in a second lateral direction and a vertical direction, each semiconductor pattern including a channel region, a first impurity region, and a second impurity region, and the first impurity region and the second impurity region being arranged in the first lateral direction with the channel region therebetween, wherein the second lateral direction intersects with the first lateral direction, a word line surrounding the semiconductor pattern and extending in the second lateral direction, a bit line electrically connected to the first impurity region of the semiconductor pattern, the bit line extending in the vertical direction, and a cell capacitor electrically connected to the second impurity region of the semiconductor pattern, wherein the first impurity region and the second impurity region of the semiconductor pattern have P-type conductivity.

According to a further aspect of the inventive concept, an integrated circuit memory device is provided with a semiconductor pattern, which includes a first source/drain impurity region, a second source/drain impurity region and a channel region extending in series between the first and second source/drain impurity regions. A dual work function word line is provided, which includes a first material having a first work function on a first portion of the channel region, and a second material having a second work function greater than the first work function on at least a second portion of the channel region. A bit line is electrically connected to the first source/drain impurity region, and a first node of a memory cell storage device is electrically connected to the second source/drain impurity region. This first node may correspond to a capacitor electrode in the event the memory device is a DRAM device; however, other configurations may also be possible in the event the memory device is an SRAM device, etc. In some embodiments, the word line may wrap around the channel region, and the first and second source/drain impurity regions may be net P-type impurity regions. In addition, the second material within the word line may include a first region extending adjacent the first source/drain impurity region, and a second region extending adjacent the second source/drain impurity region. And, the first material within the word line may be sandwiched between the first and second regions.

### BRIEF DESCRIPTION OF THE DRAWINGS

Embodiments will be more clearly understood from the following detailed description taken in conjunction with the accompanying drawings in which:

FIG. 1 is a perspective view of a semiconductor memory device according to embodiments;

FIG. 2 is a circuit diagram of a memory cell area shown in FIG. 1;

FIG. 3 is a schematic perspective view of a memory cell area of a semiconductor memory device according to embodiments;

FIG. 4 is a cross-sectional view taken along line A1-A1′ of FIG. 3;

FIG. 5 is a cross-sectional view taken along line B1-B1′ of FIG. 3;

FIG. 6 is an enlarged view of portion CX1 of FIG. 4;

FIG. 7 is a schematic layout diagram of a semiconductor memory device according to embodiments;

FIGS. 8A, 8B, 9A, 9B, 10A, 10B, 11A, 11B, 12, 13, 14A, and 14B are schematic diagrams of a method of manufacturing a semiconductor memory device, according to embodiments;

FIG. 15 is a schematic perspective view of a memory cell area of a semiconductor memory device, according to embodiments;

FIG. 16 is a cross-sectional view taken along line A2-A2′ of FIG. 15;

FIGS. 17 to 19 are schematic diagrams of a method of manufacturing a semiconductor memory device, according to embodiments;

FIG. 20 is a schematic perspective view of a memory cell area of a semiconductor memory device according to embodiments;

FIG. 21 is a cross-sectional view taken along line A3-A3′ of FIG. 20;

FIG. 22 is a cross-sectional view taken along line B3-B3′ of FIG. 20; and

FIG. 23 is an enlarged view of portion CX2 of FIG. 21.

### DETAILED DESCRIPTION OF EMBODIMENTS

Hereinafter, embodiments will be described in detail with reference to the accompanying drawings. The same reference numerals are used to denote the same elements in the drawings, and repeated descriptions thereof will be omitted.

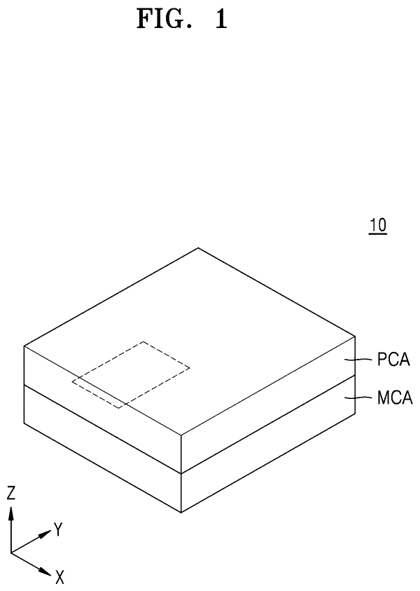

FIG. 1 is a block diagram of a semiconductor memory device 10 according to embodiments, which is shown as including a memory cell area MCA and a peripheral circuit area PCA located at a higher vertical level than the memory cell area MCA. In some embodiments, the memory cell area MCA may be a memory cell area of a dynamic random access memory (DRAM) device, and the peripheral circuit area PCA may be a core area or a peripheral circuit area of the DRAM device. For example, the peripheral circuit area PCA may include a peripheral circuit transistor configured to transmit signals and/or power to a memory cell array included in the memory cell area MCA. In some embodiments, the peripheral circuit transistor may configure various circuits, such as a command decoder, a control logic, an address buffer, a row decoder, a column decoder, a sense amplifier, a data input/output (I/O) circuit.

As shown, FIG. 1 illustrates an example in which the peripheral circuit area PCA is at a higher vertical level (in the “z” direction) than the memory cell area MCA, for example, such that the peripheral circuit area PCA is located on the memory cell area MCA. However, in some embodiments, the semiconductor device 10 may be reversed such that the memory cell area MCA is at a higher vertical level than the peripheral circuit area PCA.

In some embodiments, the peripheral circuit area PCA and the memory cell area MCA may be respectively formed on separate wafers and then adhered to each other by using bonding pads. In other embodiments, after the peripheral circuit area PCA is first formed on a peripheral circuit wafer, the memory cell area MCA may be formed on the peripheral circuit area PCA.

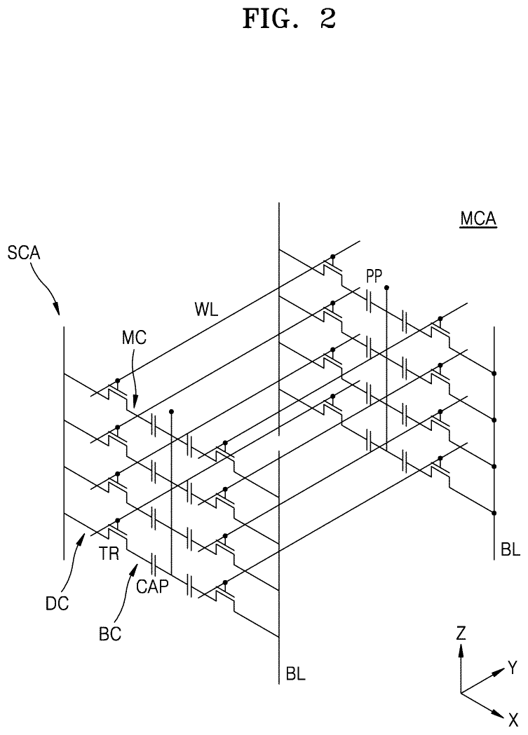

FIG. 2 is a circuit diagram of the memory cell area MCA shown in FIG. 1.

Referring to FIG. 2, a memory cell area MCA may include a plurality of sub-cell arrays SCA. The plurality of sub-cell arrays SCA may be arranged apart from each other in a second lateral direction Y. In some embodiments, the sub-cell array SCA may include a plurality of bit lines BL, a plurality of word lines WL, and a plurality of memory cells MC. Each of the plurality of memory cells MC may include one cell transistor TR and one cell capacitor CAP connected to the one cell transistor TR. Each of the plurality of memory cells MC may have a 1-transistor/1-capacitor (1T1C) structure.

In some embodiments, the plurality of word lines WL may extend in the second lateral direction Y and be arranged apart from each other in each of a first lateral direction X and a vertical direction Z. The plurality of bit lines BL may extend in the vertical direction Z and be arranged apart from each other in each of the first lateral direction X and the second lateral direction Y. One cell transistor TR may be between one word line WL and one bit line BL.

In some embodiments, a gate of the cell transistor TR may be connected to the word line WL, and a source of the cell transistor TR may be connected to the bit line BL through a first contact DC. The cell transistor TR may be connected to the cell capacitor CAP through a second contact BC. A drain of the cell transistor TR may be connected to a first electrode of the cell capacitor CAP through the second contact BC, and a second electrode of the cell capacitor CAP may be connected to the plate electrode PP.

In some embodiments, in one sub-cell array SCA, a plurality of cell transistors TR may overlap each other in the vertical direction Z. In the one sub-cell array SCA, a plurality of cell capacitors CAP may overlap each other in the vertical direction Z. One cell transistor TR and one cell capacitor CAP may be arranged in parallel at the same vertical level, and a plurality of memory cells MC, each of which includes one cell transistor TR and one cell capacitor CAP, may be stacked in the vertical direction Z. A storage capacity of the sub-cell array SCA may vary depending on the number or layer number of memory cells MC (e.g., the number or layer number of cell capacitors CAP) stacked in the vertical direction Z.

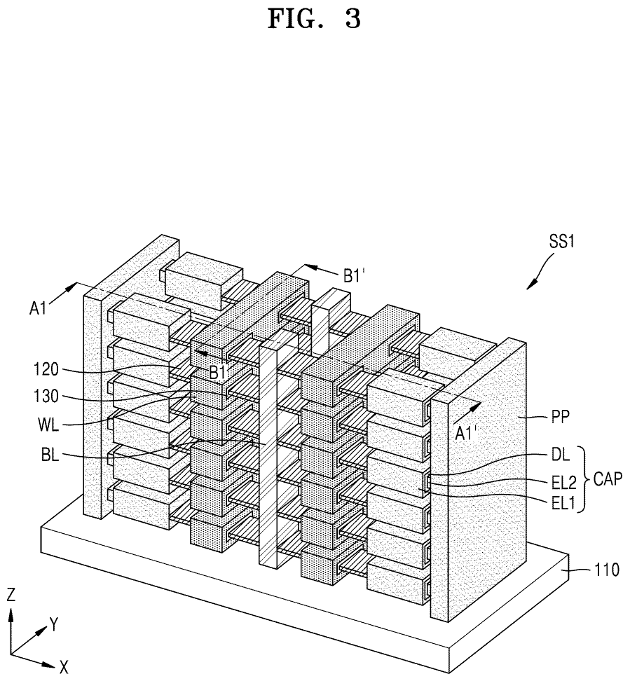

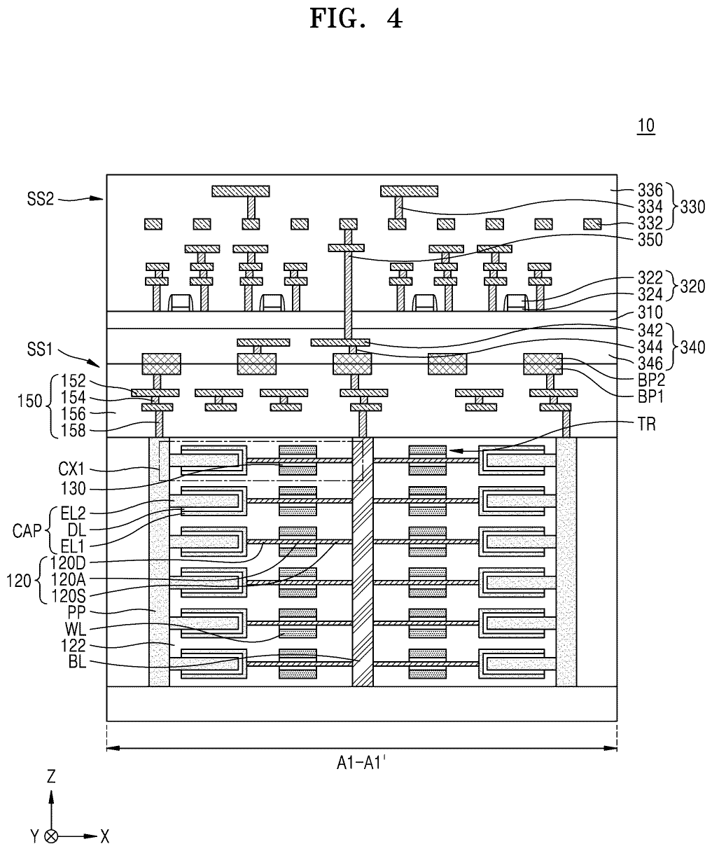

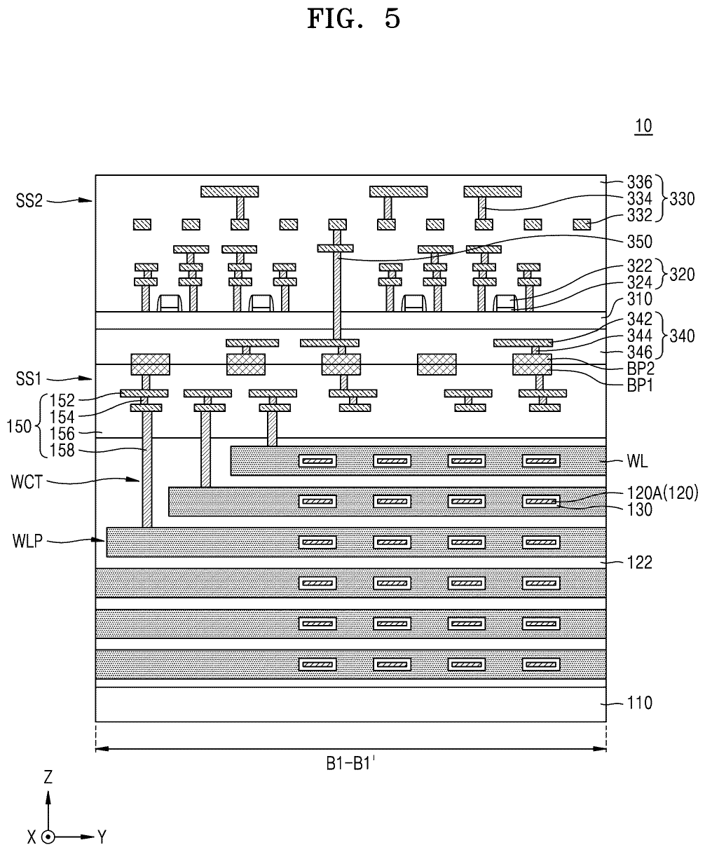

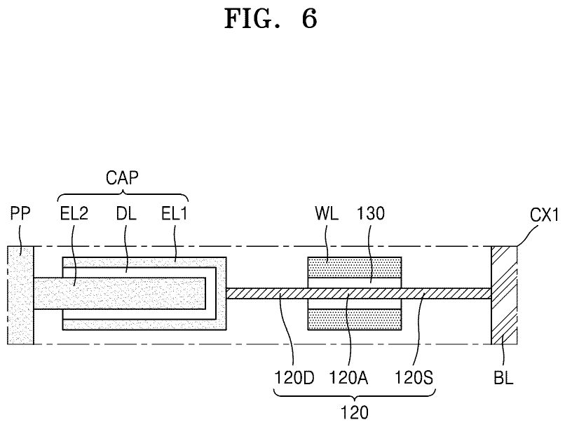

FIG. 3 is a perspective view of a memory cell area of a semiconductor memory device according to embodiments. FIG. 4 is a cross-sectional view taken along line A1-A1′ of FIG. 3, whereas FIG. 5 is a cross-sectional view taken along line B1-B1′ of FIG. 3, and FIG. 6 is an enlarged view of portion CX1 of FIG. 4. Referring to FIGS. 3 to 6, a semiconductor memory device 10 may include a first stack structure SS1 and a second stack structure SS2, and the second stack structure SS2 may be bonded onto the first stack structure SS1 by first and bonding pads BP1 and BP2.

In some embodiments, the first stack structure SS1 may include a first substrate 110 and a plurality of semiconductor patterns 120, a plurality of bit lines BL, a plurality of word lines WL, and corresponding cell capacitors CAP, which are on the first substrate 110. In some embodiments, the first substrate 110 may include silicon (Si), germanium (Ge), or silicon germanium (SiGe). In some embodiments, the first substrate 110 may include a silicon-on-insulator (SOI) substrate or a germanium-on-insulator (GeOI) substrate.

In some embodiments, on the first substrate 110, the plurality of semiconductor patterns 120 may extend “lengthwise” in a first lateral direction X and be spaced apart from each other in a vertical direction Z. In some embodiments, the plurality of semiconductor patterns 120 may include, for example, an undoped semiconductor material or a doped semiconductor material. In some embodiments, the plurality of semiconductor patterns 120 may include polysilicon. In some embodiments, the plurality of semiconductor patterns 120 may include an amorphous metal oxide, a polycrystalline metal oxide, or a combination thereof, for example, at least one of indium (In)-gallium (Ga)-based oxide (IGO), In-zinc (Zn)-based oxide (IZO), and In—Ga—Zn-based oxide (IGZO). In some other embodiments, the plurality of semiconductor patterns 120 may include a 2D material semiconductor. For example, the 2D material semiconductor may include MoS₂, WSe₂, graphene, carbon nanotube, or a combination thereof.

In some embodiments, the plurality of semiconductor patterns 120 may each have a line shape or bar shape extending in the first lateral direction X, and each of the semiconductor patterns 120 may include a channel region 120A, a first impurity region 120S, and a second impurity region 120D. The first impurity region 120S and the second impurity region 120D may be arranged in the first lateral direction X with the channel region 120A therebetween. The first impurity region 120S may be connected to the bit line BL, and the second impurity region 120D may be connected to the cell capacitor CAP. An ohmic metal layer including a metal silicide may be further formed between the first impurity region 120S and the bit line BL and between the second impurity region 120D and the cell capacitor CAP.

In some embodiments, the first impurity region 120S and the second impurity region 120D may have P-type conductivity. For example, the first impurity region 120S and the second impurity region 120D may include P-type impurities, such as boron (B), gallium (Ga), or aluminum (Al). For example, the first impurity region 120S and the second impurity region 120D may include polysilicon doped with the P-type impurities.

In some embodiments, the first impurity region 120S and the second impurity region 120D may have P-type conductivity, and thus, the cell transistor TR of the semiconductor memory device 10 according to the inventive concept may form a p-type field-effect transistor (pFET). When the cell transistor TR forms the pFET, electrical properties of the semiconductor memory device 10 according to the inventive concept may improve.

As will be understood by those skilled in the relevant art, a three-dimensional (3D) semiconductor memory device according to a comparative example may turn on a parasitic bipolar transistor due to a floating body effect, and thus, static and dynamic refresh characteristics of the 3D semiconductor memory device may deteriorate. However, advantageously, when the cell transistor TR of the semiconductor memory device 10 forms the pFET, the floating body effect may be suppressed. A turn-on current Id of the parasitic bipolar transistor due to the floating body effect may be expressed as shown in Equation 1:

$$Id = ( 1 + β ) IGIDL$$

Specifically, when the cell transistor TR forms the pFET, holes may have a relatively large effective mass, and thus, a gate-induced drain leakage (GIDL) current IGIDL may be reduced. In addition, when the cell transistor TR forms the pFET, a bipolar gain value β of the parasitic bipolar transistor may be lowered. In the case of the pFET, because the mobility of holes in an emitter is relatively low, and the recombination time of electron-hole pairs in a base where charges accumulate is fast, the bipolar gain value β may be lowered. As a result, the semiconductor memory device 10 according to the inventive concept may suppress the floating body effect by using the cell transistor TR that forms the pFET, and thus, electrical properties of the semiconductor memory device 10 may improve. Furthermore, because the cell transistor TR has a great size, the 3D semiconductor memory device 10 according to the inventive concept may maintain IDR characteristics, even when the pFET is used.

In some embodiments, the plurality of word lines WL may include at least one of a doped semiconductor material (e.g., doped silicon and doped germanium), a conductive metal nitride (e.g., titanium nitride and tantalum nitride), a metal (e.g., tungsten, titanium, and tantalum), and a metal-semiconductor compound (e.g., tungsten silicide, cobalt silicide, and titanium silicide).

In some embodiments, a gate insulating layer 130 may be between the word line WL and the semiconductor pattern 120. The gate insulating layer 130 may include at least one selected from a high-k dielectric material having a higher dielectric constant than silicon oxide and a ferroelectric material. In some embodiments, the gate insulating layer 130 may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

In some embodiments, the plurality of bit lines BL may extend in the vertical direction Z on the first substrate 110 and be apart from each other in the second lateral direction Y. The plurality of bit lines BL may include any one of a doped semiconductor material, a conductive metal nitride, a metal, and a metal-semiconductor compound.

In some embodiments, the cell capacitor CAP may include a first electrode EL1, a capacitor dielectric layer DL, and a second electrode EL2. First electrodes EL1 may each extend in the first lateral direction X and be apart from each other in the vertical direction Z. The first electrode EL1 may have an inner space (not shown) extending in the first lateral direction X, and the inner space of the first electrode EL1 may be filled by the capacitor dielectric layer DL and the second electrode EL2. For example, the first electrode EL1 may have a cup shape rotated by 90 degrees.

In some embodiments, the capacitor dielectric layer DL may include at least one selected from a high-k dielectric material having a higher dielectric constant than silicon oxide and a ferroelectric material. In some embodiments, the capacitor dielectric layer DL may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

In some embodiments, the second electrode EL2 may fill the inner space of the first electrode EL1, and the capacitor dielectric layer DL may be between the inner space of the first electrode EL1 and the second electrode EL2. In some embodiments, the first electrode EL1 and the second electrode EL2 may include a doped semiconductor material, a conductive metal nitride (e.g., titanium nitride, tantalum nitride, niobium nitride, or tungsten nitride), a metal (e.g., ruthenium, iridium, titanium, or tantalum), or a conductive metal oxide (e.g., iridium oxide or niobium oxide).

In some embodiments, a plate electrode PP may be arranged on one side of the cell capacitor CAP and extend in the vertical direction Z and the second lateral direction Y. The second electrode EL2 of the cell capacitor CAP may be electrically connected to the plate electrode PP. For example, the plate electrode PP may be connected in common to a plurality of second electrodes EL2, which are apart from each other in the vertical direction Z, and a plurality of second electrodes EL2, which are apart from each other in the second lateral direction Y.

In some embodiments, a mold insulating layer 122 may be between two adjacent semiconductor patterns 120, which are apart from each other in the vertical direction Z, two adjacent word lines WL, which are apart from each other in the vertical direction Z, and two adjacent first electrodes EL1, which are apart from each other in the vertical direction Z. In addition, the mold insulating layer 122 may also be between two bit lines BL, which are apart from each other in the second lateral direction Y.

In some embodiments, the mold insulating layer 122 may include silicon oxide, silicon oxynitride, silicon nitride, carbon-containing silicon oxide, carbon-containing silicon oxynitride carbon-containing silicon nitride, or a combination thereof. In some embodiments, the mold insulating layer 122 may include a plurality of insulating layers. Here, the plurality of insulating layers, which are formed between the plurality of bit lines BL, between the plurality of word lines WL, between the plurality of semiconductor patterns 120, and between a plurality of cell capacitors CAP using a manufacturing process adopted for forming a 3D structure, may be collectively referred to as the mold insulating layer 122.

In some embodiments, the first stack structure SS1 may include an upper wiring structure 150. The upper wiring structure 150 may include a wiring layer 152, a via 154, and an insulating layer 156. The upper wiring structure 150 may further include a contact 158 electrically connected to the bit line BL, the word line WL, and the plate electrode PP. In addition, the first bonding pad BP1 may be formed on the upper wiring structure 150 and located on the same plane as an uppermost surface of the insulating layer 156.

In some embodiments, the second stack structure SS2 may include a second substrate 310, a peripheral circuit transistor 320 on the second substrate 310, a frontside wiring structure 330 covering the peripheral circuit transistor 320 on a top surface of the second substrate 310, and a backside wiring structure 340 on a bottom surface of the second substrate 310. The frontside wiring structure 330 may include a wiring layer 332, a via 334, and an insulating layer 336, and the backside wiring structure 340 may include a wiring layer 342, a via 344, and an insulating layer 346.

In some embodiments, the backside wiring structure 340 may include the second bonding pad BP2 on the same plane as a bottom surface of the insulating layer 346. Because the first bonding pad BP1 is connected to the second bonding pad BP2, the first stack structure SS1 may be bonded to the second stack structure SS2. In some embodiments, the first stack structure SS1 may be adhered to the second stack structure SS2 by using a copper-oxide hybrid bonding method. In some embodiments, the first bonding pad BP1 and the second bonding pad BP2 may include copper or an alloy thereof. An interface between the insulating layer 156 of the upper wiring structure 150 and the insulating layer 346 of the backside wiring structure 340 may extend planar and be on the same plane as an interface between the first bonding pad BP1 and the second bonding pad BP2.

In some embodiments, the peripheral circuit transistor 320 may include a gate electrode 322 and a gate insulating layer 324, which are on an active region of the second substrate 310. In some embodiments, the peripheral circuit transistor 320 may include sense amplifiers, which are electrically connected to the bit lines BL included in the first stack structure SS1. In addition, the peripheral circuit transistor 320 may include sub-word line drivers, which may be electrically connected to the word lines WL included in the first stack structure SS1.

In some embodiments, the second stack structure SS2 may further include a through via 350 passing through the second substrate 310. The wiring layer 332 included in the frontside wiring structure 330 may be electrically connected to the wiring layer 342 included in the backside wiring structure 340 by the through via 350. In addition, the wiring layer 342 included in the backside wiring structure 340 may be electrically connected to the wiring layer 152 included in the upper wiring structure 150 through the second bonding pad BP2 and the first bonding pad BP1.

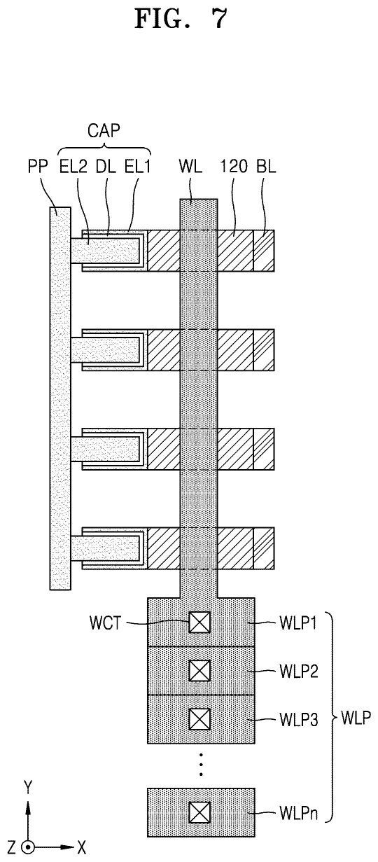

FIG. 7 is a layout diagram of a semiconductor memory device according to embodiments. Referring to FIGS. 5 and 7, a word line WL may extend in a second lateral direction Y to intersect with a first lateral direction X, which is a direction in which the semiconductor pattern 120 extends. A word line pad WLP may be arranged on an end portion of the word line WL. As shown in FIG. 7, a plurality of word line pads WLP may be sequentially arranged in the second lateral direction Y. As shown in FIG. 5, a plurality of word line pads WLP may be arranged in a staircase form in the second lateral direction Y.

In some embodiments, a first word line pad WLP1 connected to an uppermost one of word lines WL, a second word line pad WLP2 connected to a word line WL located under the uppermost one of the word lines WL, a third word line pad WL3 connected to a word line WL located under two uppermost ones of the word lines WL, . . . , and an n-th word line pad WLPn connected to an n-th word line WL, which is placed n-th from a top of the word lines WL, may be arranged in the second lateral direction Y.

A word line contact WCT may be on a top surface of each of the word line pads WLP, and the word line WL may be electrically connected to an upper wiring structure 150 by the word line contact WCT.

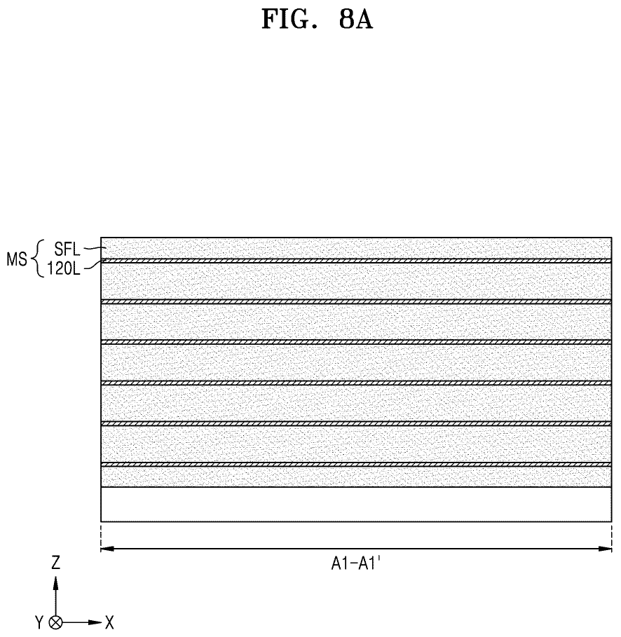

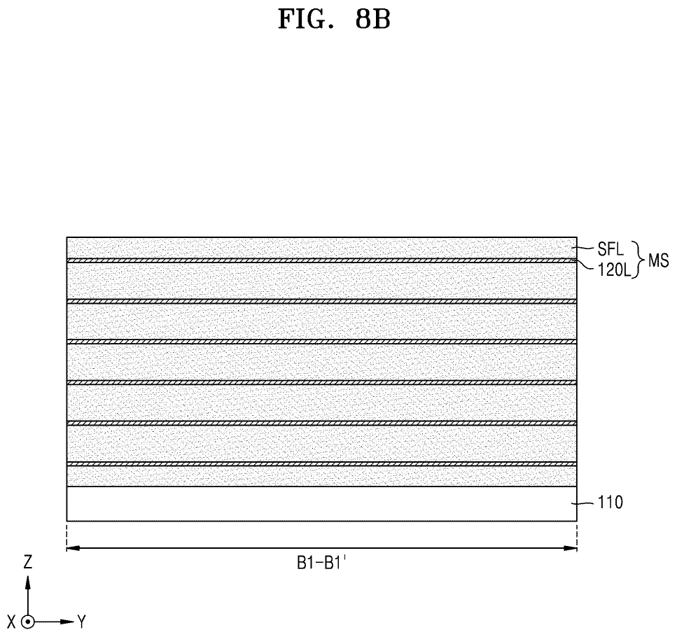

FIGS. 8A, 8B, 9A, 9B, 10A, 10B, 11A, 11B, 12, 13, 14A, and 14B are schematic diagrams of a method of manufacturing a semiconductor memory device, according to embodiments. Referring to FIGS. 8A and 8B, a sacrificial mold layer SFL and a semiconductor layer 120L may be alternately and sequentially formed on a first substrate 110 to form a mold stack MS. In some embodiments, the sacrificial mold layer SFL and the semiconductor layer 120L may be formed using materials having an etch selectivity with respect to each other. For example, each of the sacrificial mold layer SFL and the semiconductor layer 120L may include a single crystalline layer including a Group-IV semiconductor, a Group II-VI compound semiconductor, or a Group III-V compound semiconductor. The sacrificial mold layer SFL and the semiconductor layer 120L may include different materials. In an embodiment, the sacrificial mold layer SFL may include SiGe, and the semiconductor layer 120L may include single-crystalline silicon. Each of the sacrificial mold layer SFL and the semiconductor layer 120L may have a thickness of several tens of nm.

In some embodiments, the sacrificial mold layer SFL and the semiconductor layer 120L may be formed by using an epitaxy process. For example, the epitaxy process may include a vapor-phase epitaxy (VPE) process, a chemical vapor deposition (CVD) process (e.g., an ultra-high vacuum chemical vapor deposition (UHV-CVD) process), a molecular beam epitaxy process, or a combination thereof. In the epitaxy process, a liquid or gaseous precursor may be used as a precursor required for forming the sacrificial mold layer SFL and the semiconductor layer 120L.

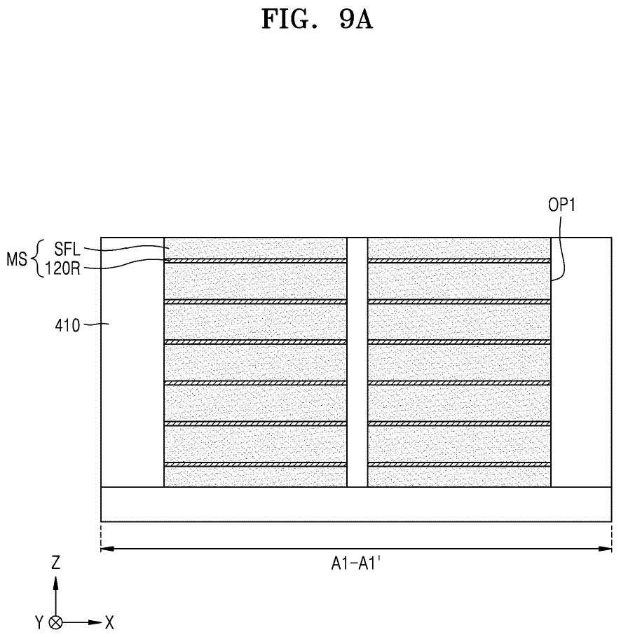

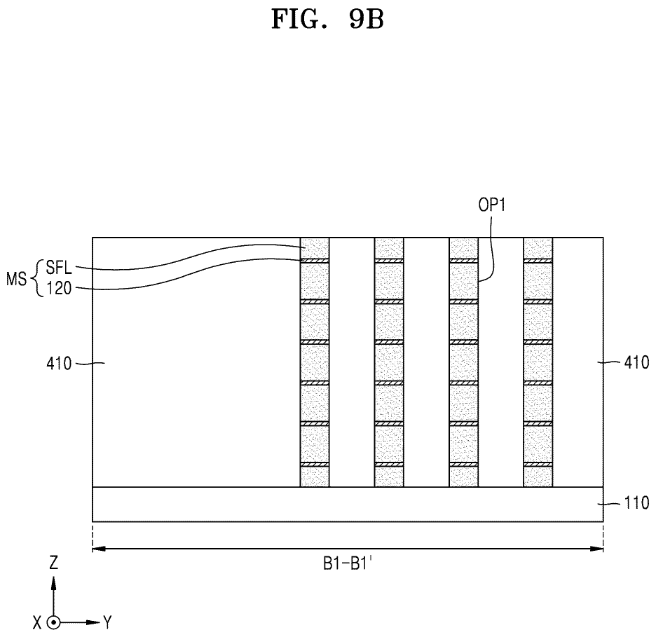

Referring to FIGS. 9A and 9B, a mask pattern (not shown) may be formed on the mold stack MS, and a portion of the mold stack MS may be removed by using the mask pattern as an etch mask to form a first opening OP1. Subsequently, an insulating layer 410 may be formed inside the first opening OP1.

In some embodiments, by forming the first opening OP1, a plurality of semiconductor patterns 120 may be formed from the semiconductor layer 120L. Here, the plurality of semiconductor patterns 120 may be formed by patterning portions of the semiconductor layer 120L.

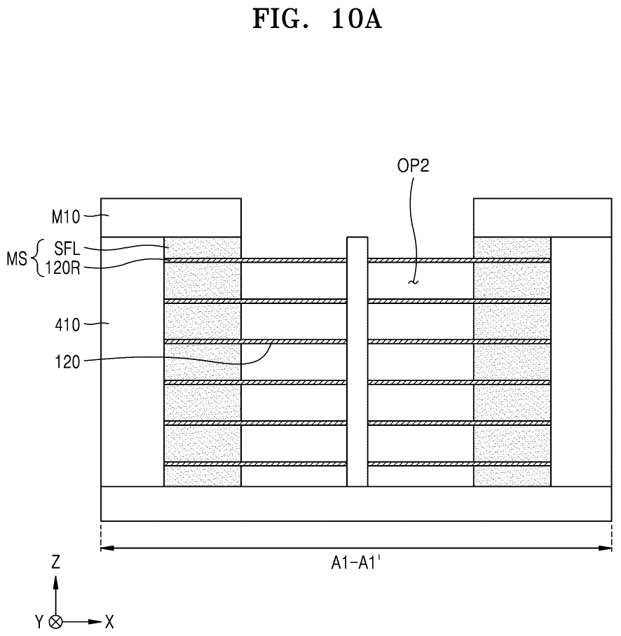

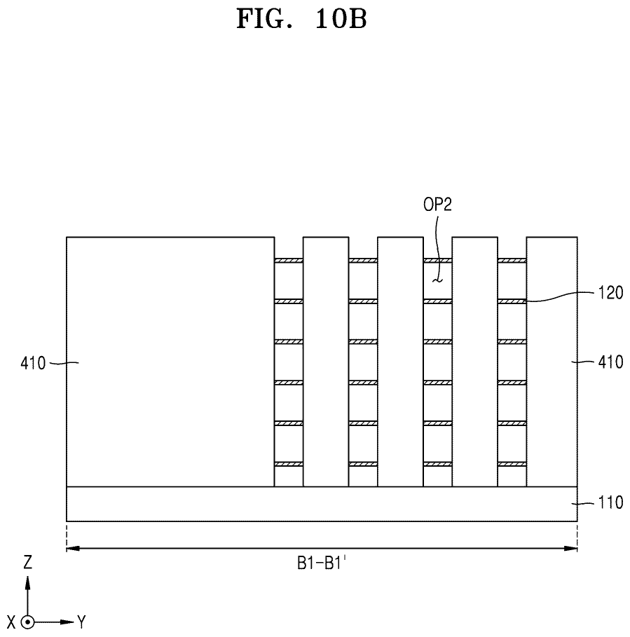

Referring to FIGS. 10A and 10B, the sacrificial mold layer SFL may be removed, and thus, a second opening OP2 may be formed between the plurality of semiconductor patterns 120. In some embodiments, a mask pattern M10 may be formed on the mold stack MS. A portion of the sacrificial mold layer SFL that is not covered by the mask pattern M10 may be removed, and portions of the sacrificial mold layer SFL, which vertically overlap the mask pattern M10, may not be removed but remain. Here, a portion of the semiconductor pattern 120 covered by the sacrificial mold layer SFL may be referred to as a residual pattern 120R. The mask pattern M10 may be arranged on a structure in which the residual pattern 120R and the sacrificial mold layer SFL are alternately stacked.

In some embodiments, the process of removing the sacrificial mold layer SFL may include a wet etching process or a pullback process. For example, the process of removing the sacrificial mold layer SFL may include an etching process using an etch selectivity between the sacrificial mold layer SFL and the semiconductor layer 120L. For example, during the wet etching process or the pullback process, an etch rate of the plurality of semiconductor patterns 120 may be relatively low, and an etch rate of the sacrificial mold layer SFL may be relatively high.

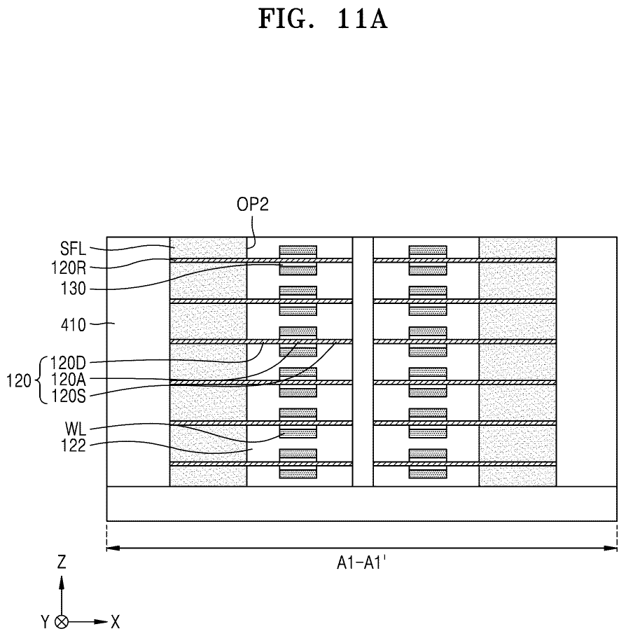

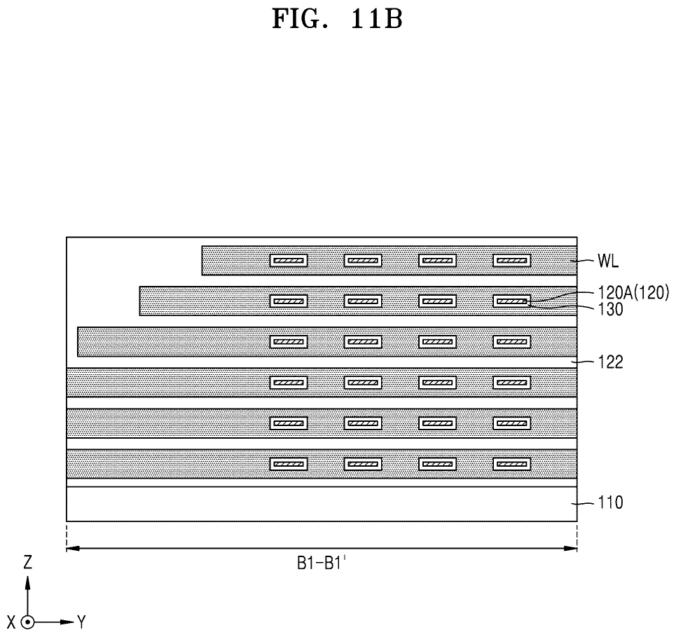

Referring to FIGS. 11A and 11B, a gate insulating layer 130 and a word line WL may be sequentially formed on a top surface, a side surface, and a bottom surface of each of the plurality of semiconductor patterns 120 inside the second opening OP2. For example, the gate insulating layer 130 may conformally surround the plurality of semiconductor patterns 120, and the word line WL may surround the plurality of semiconductor patterns 120 on the gate insulating layer 130 and extend in the second lateral direction Y.

In some embodiments, portions of the gate insulating layer 130 and the word line WL on both end portions of each of the plurality of semiconductor patterns 120 (e.g., both end portions of each of the plurality of semiconductor patterns 120 in a first lateral direction X) may be removed inside the second opening OP2. In other embodiments, a protective layer (not shown) covering both end portions of each of the plurality of semiconductor patterns 120 may be first formed inside the second opening OP2, and the gate insulating layer 130 and the word line WL may be then formed to surround a central portion of each of the plurality of semiconductor patterns 120. Thereafter, the protective layer may be removed, and thus, both end portions of each of the plurality of semiconductor patterns 120 may not be covered by the gate insulating layer 130 and the word line WL but be exposed again.

Thereafter, a first impurity region 120S and a second impurity region 120D may be formed. The first impurity region 120S and the second impurity region 120D may be formed in both end portions of the semiconductor pattern 120, which are exposed by removing portions of the gate insulating layer 130 and the word line WL.

In some embodiments, the first impurity region 120S and the second impurity region 120D may be formed by doping P-type impurities into the both end portions of the semiconductor pattern 120 using a gas-phase doping process. For example, the P-type impurities may include boron (B), gallium (Ga), or aluminum (Al).

In some embodiments, P-type doped polysilicon or P-type doped polysilicon germanium may be brought into contact with the both end portions of the semiconductor pattern 120, and thus, P-type impurities may be doped into the first impurity region 120S and the second impurity region 120D. In addition, the process of bringing the P-type doped polysilicon or the P-type doped polysilicon germanium into contact with the both end portions of the semiconductor pattern 120 may be performed simultaneously with the gas-phase doping process.

Subsequently, a mold insulating layer 122 may be formed to fill the inside of the second opening OP2. In some embodiments, the mold insulating layer 122 may be located between two word lines WL, which are adjacent to each other in a vertical direction Z, and between the end portions of two semiconductor patterns 120, which are adjacent to each other in the vertical direction Z.

In some embodiments, a portion of the word line WL may be removed to form a word line pad WLP (refer FIG. 5). Word line pads WLP may be arranged in a staircase form. For example, a word line pad WLP connected to one word line WL may be apart from a word line pad WLP connected to another word line located under the one word line WL in the second lateral direction Y.

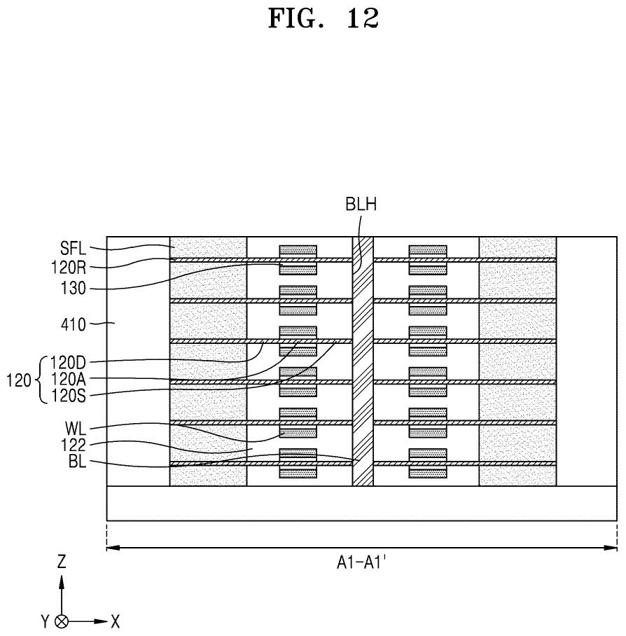

Referring to FIG. 12, a portion of the insulating layer 410 may be removed to form a bit line opening BLH, and a bit line BL may be formed inside the bit line opening BLH. In some embodiments, two semiconductor patterns 120 may be apart from each other with the bit line BL therebetween. A first sidewall of one bit line BL may be in contact with the first impurity region 120S of one semiconductor pattern 120, and a second sidewall of the one bit line BL may be in contact with the first impurity region 120S of another semiconductor pattern 120. That is, two semiconductor patterns 120 located at the same vertical level may be electrically connected to one bit line BL, but the inventive concept is not limited thereto.

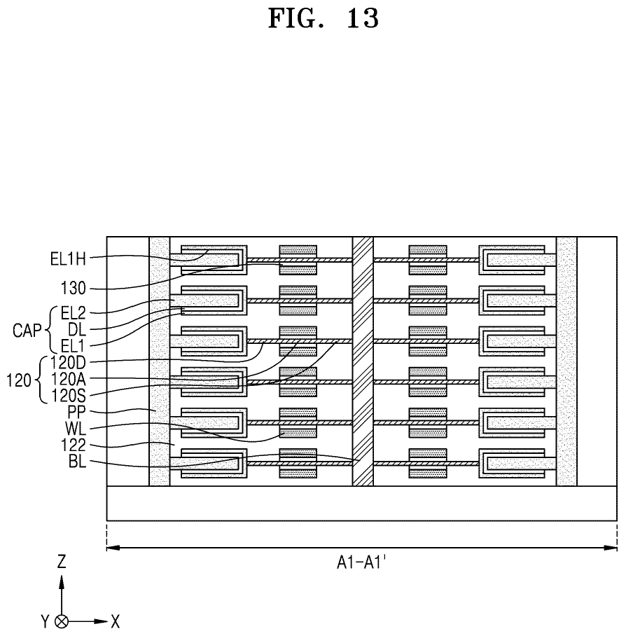

Referring to FIG. 13, the sacrificial mold layer SFL and the residual pattern 120R may be removed, and a cell capacitor CAP may be formed at a location where the sacrificial mold layer SFL1 and the residual pattern 120R are removed. In some embodiments, the cell capacitor CAP may include a first electrode EL1, a capacitor dielectric layer DL, and a second electrode EL2. The first electrode EL1 may be electrically connected to the second impurity region 120D of the semiconductor pattern 120 and have an inner space EL1H that extends in the first lateral direction X. The capacitor dielectric layer DL may be conformally located inside the inner space EL1H, and the inner space EL1H may be filled by the second electrode EL2. Subsequently, a plate electrode PP may be electrically connected to the second electrode EL2 and extend in the second lateral direction Y.

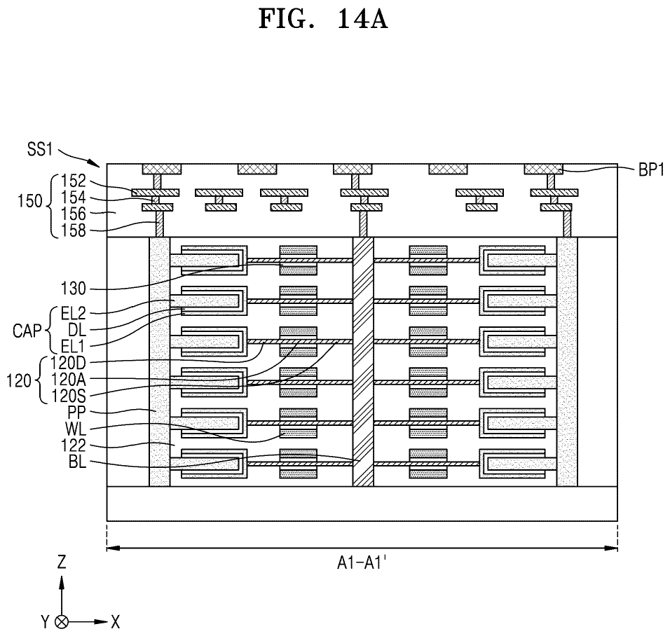

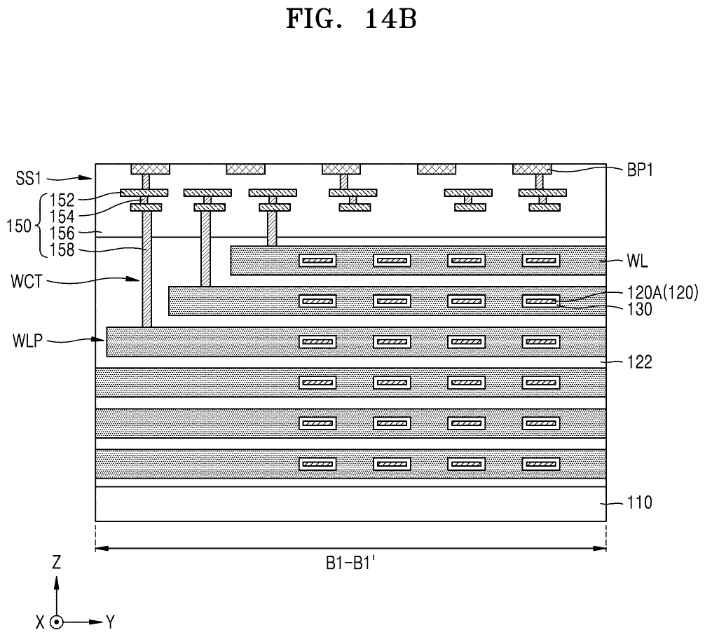

Referring to FIGS. 14A and 14B, an upper wiring structure 150 may be formed. The upper wiring structure 150 may include a wiring layer 152, a via 154, an insulating layer 156, and a contact 158. For example, the contact 158 may be electrically connected to the bit line BL, the word line WL, and the plate electrode PP. Thereafter, a first bonding pad BP1 may be formed on the upper wiring structure 150 and located on the same plane as an uppermost surface of the insulating layer 156.

Referring back to FIGS. 4 and 5, a second stack structure SS2 may be prepared. In particular, in some embodiments, the second stack structure SS2 may include a second substrate 310, a peripheral circuit transistor 320 on the second substrate 310, a frontside wiring structure 330 covering the peripheral circuit transistor 320 on a top surface of the second substrate 310, and a backside wiring structure 340 on a bottom surface of the second substrate 310.

In some embodiments, a peripheral circuit transistor 320 may be formed on a first surface (or the top surface) of the second substrate 310, the frontside wiring structure 330 may be formed on the front surface of the second substrate 310, and a carrier substrate may be adhered onto the frontside wiring structure 330. Thereafter, a second surface (or the bottom surface) of the second substrate 310 may be ground to thin the second substrate 310. Thereafter, the backside wiring structure 340 and a second bonding pad BP2 may be formed on the second surface of the second substrate 310, and thus, the second stack structure SS2.

Subsequently, the second stack structure SS2 may be bonded to a first stack structure SS1. In this case, the first bonding pad BP1 of the first stack structure SS1 may be bonded to the second bonding pad BP2 of the second stack structure SS2, and a top surface of the upper insulating layer 156 may be bonded to a bottom surface of an insulating layer 346.

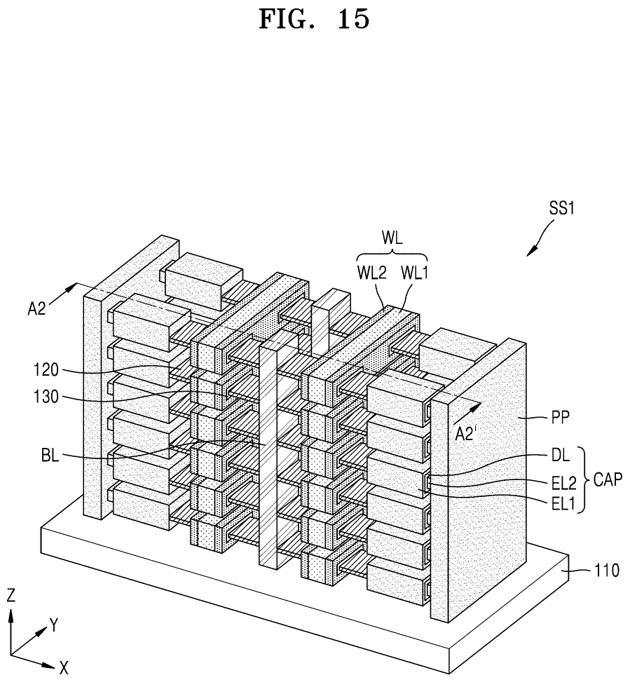

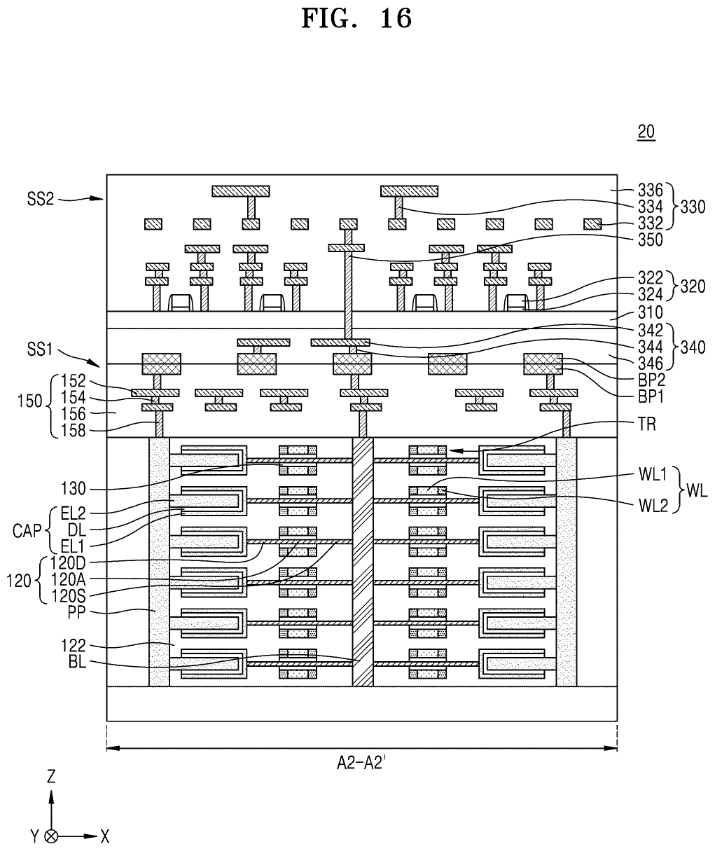

FIG. 15 is a perspective view of a memory cell area of a semiconductor memory device according to embodiments. FIG. 16 is a cross-sectional taken along line A2-A2′ of FIG. 15. Referring to FIGS. 15 and 16, each of a plurality of word lines WL may include a first word line WL1 and a second word line WL2. A plurality of first word lines WL1 may surround a plurality of semiconductor patterns 120. The plurality of first word lines WL1 may extend in a second lateral direction Y and be apart from each other in a vertical direction Z. In this case, a gate insulating layer 130 may be between the first word line WL1 and the semiconductor pattern 120 and between the second word line WL2 and the semiconductor pattern 120.

In some embodiments, one of the first word lines WL1 may extend in the second lateral direction Y while surrounding a plurality of semiconductor patterns 120, which are apart from each other in the second lateral direction Y. From among the plurality of first word lines WL1, two first word lines WL1, which are apart from each other in the vertical direction Z, may overlap each other in the vertical direction Z.

In some embodiments, second word lines WL2 may form a pair. A pair of second word lines WL2 may be apart from each other in a first lateral direction X with the first word line WL1 therebetween. Each of the pair of second word lines WL2 may be in contact with the first word line WL1. In this case, the pair of second word lines WL2 may have the same width in a first lateral direction X.

In some embodiments, the first word line WL1 may surround a central portion of a channel region 120A of the semiconductor pattern 120. The second word line WL2 may surround an edge portion of the channel region 120A of the semiconductor pattern 120. For example, the second word line WL2 may surround a boundary between a first impurity region 120S and the channel region 120A and a boundary between the second impurity region 120D and the channel region 120A. Here, the edge portion of the channel region 120A of the semiconductor pattern 120 may refer to a portion of the channel region 120A, which is adjacent to the first impurity region 120S and the second impurity region 120D. In this case, the first word line WL1 and the second word line WL2 may have the same thickness in the vertical direction Z.

In some embodiments, a plurality of second word lines WL2 may surround the plurality of semiconductor patterns 120. The plurality of second word lines WL2 may extend in the second lateral direction Y and be apart from each other in the vertical direction Z. In some embodiments, one of the second word lines WL2 may extend in the second lateral direction Y while surrounding the plurality of semiconductor patterns 120, which are apart from each other in the second lateral direction Y. From among the plurality of second word lines WL2, two second word lines WL2, which are apart from each other in the vertical direction Z, may overlap each other in the vertical direction Z.

In some embodiments, the first word line WL1 and the second word line WL2 may include at least one of a doped semiconductor material (e.g., doped silicon and doped germanium), a conductive metal nitride (e.g., titanium nitride and tantalum nitride), a metal (e.g., tungsten, titanium, and tantalum), and a metal-semiconductor compound (e.g., tungsten silicide, cobalt silicide, and titanium silicide).

In some embodiments, the first word line WL1 and the second word line WL2 may include different materials. The first word line WL1 and the second word line WL2 may include materials having different work functions. The first word line WL1 may include a first material having a first work function, and the second word line WL2 may include a second material having a second work function, which is different from the first work function. In this case, the second work function may be larger than the first work function. In some embodiments, the first impurity region 120S and the second impurity region 120D may have P-type conductivity. For example, the first impurity region 120S and the second impurity region 120D may include P-type impurities, such as boron (B), gallium (Ga), or aluminum (Al). For example, the first impurity region 120S and the second impurity region 120D may include polysilicon doped with the P-type impurities.

In some embodiments, the first impurity region 120S and the second impurity region 120D may have P-type conductivity, and thus, a cell transistor TR of a semiconductor memory device 20 according to the inventive concept may form a pFET. When the cell transistor TR forms the pFET, a floating body effect of the semiconductor memory device 20 may be suppressed. In this case, because the second word line WL2, which surrounds the boundary between the first impurity region 120S and the channel region 120A and the boundary between the second impurity region 120D and the channel region 120A, includes a material having a larger work function than the first word line WL1, the floating body effect of the semiconductor memory device 20 may be additionally suppressed.

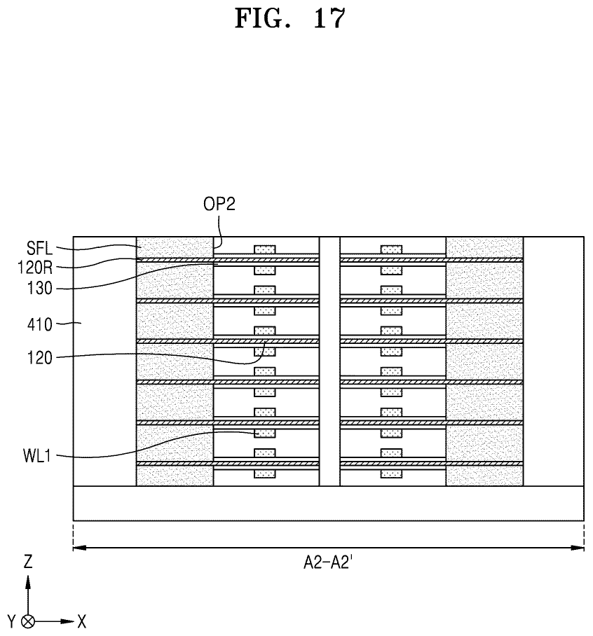

FIGS. 17 to 19 are schematic diagrams of a method of manufacturing a semiconductor memory device, according to embodiments. Referring to FIG. 17, in the resultant structure of FIG. 10A, a gate insulating layer 130 and a first word line WL1 may be sequentially formed on a top surface, a side surface, and a bottom surface of each of a plurality of semiconductor patterns 120 inside a second opening OP2.

For example, the gate insulating layer 130 may conformally surround the plurality of semiconductor patterns 120, and the first word line WL1 may surround the plurality of semiconductor patterns 120 on the gate insulating layer 130 and extend in a second lateral direction Y. In some embodiments, portions of the first word line WL1 on both end portions of each of the plurality of semiconductor patterns 120 (e.g., both end portions of each of the plurality of semiconductor patterns 120 in a first lateral direction X) may be removed inside the second opening OP2. A portion of a top surface of the gate insulating layer 130 may be covered by the first word line WL1, and the remaining portion of the top surface of the gate insulating layer 130 may be exposed.

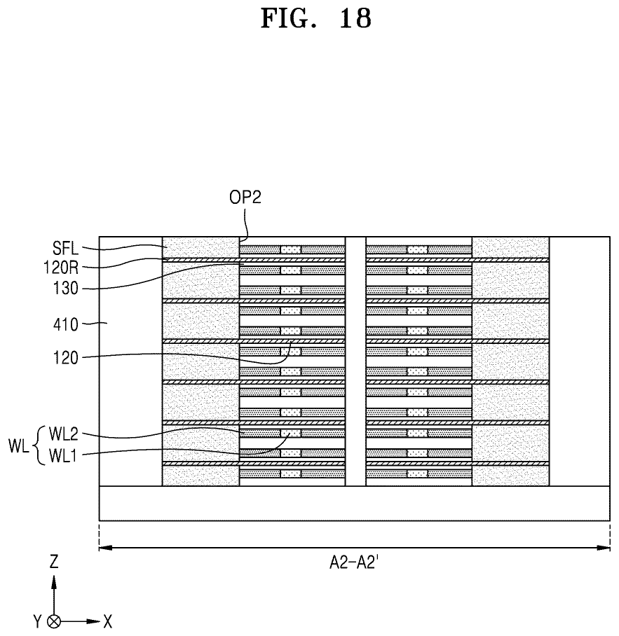

Referring to FIG. 18, a second word line WL2 may surround the plurality of semiconductor patterns 120 on the gate insulating layer 130 and extend in the second lateral direction Y. The second word line WL2 may conformally surround the gate insulating layer 130.

In some embodiments, a pair of second word lines WL2 may be apart from each other in the first lateral direction X with the first word line WL1 therebetween. Each of the pair of second word lines WL2 may be in contact with the first word line WL1. In this case, the first word line WL1 may have the same thickness as the second word line WL2 in a vertical direction Z. In some embodiments, the first word line WL1 and the second word line WL2 may include different materials. The first word line WL1 and the second word line WL2 may include materials having different work functions. In this case, a work function of the second word line WL2 may be larger than a work function of the first word line WL1.

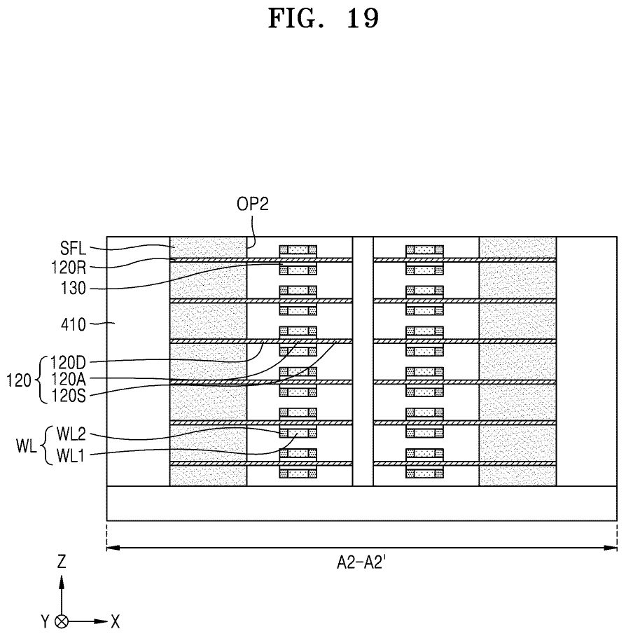

Referring to FIG. 19, portions of the gate insulating layer 130 and the second word line WL2 on both end portions of each of the plurality of semiconductor patterns 120 (e.g., both end portions of each of the plurality of semiconductor patterns 120 in the first lateral direction X) may be removed inside the second opening OP2. In other embodiments, the portions of the second word line WL2 on both end portions of each of the plurality of semiconductor patterns 120 (e.g., both end portions of each of the plurality of semiconductor patterns 120 in the first lateral direction X) may be removed, and the gate insulating layer 130 may not be removed.

Thereafter, a first impurity region 120S and a second impurity region 120D may be formed. The first impurity region 120S and the second impurity region 120D may be formed on both end portions of the semiconductor pattern 120, which are exposed by removing the portions of the gate insulating layer 130 and the second word line WL2.

In some embodiments, the first impurity region 120S and the second impurity region 120D may be formed by doping P-type impurities into the both end portions of the semiconductor pattern 120 using a gas-phase doping process. For example, P-type impurities may include boron (B), gallium (Ga), or aluminum (Al).

In some embodiments, P-type doped polysilicon or P-type doped polysilicon germanium may be brought into contact with the both end portions of the semiconductor pattern 120, and thus, P-type impurities may be doped into the first impurity region 120S and the second impurity region 120D. In addition, the process of bringing the P-type doped polysilicon or the P-type doped polysilicon germanium into contact with the both end portions of the semiconductor pattern 120 may be performed simultaneously with the gas-phase doping process.

Subsequently, a mold insulating layer 122 may be formed to fill the inside of the second opening OP2. In some embodiments, the mold insulating layer 122 may be located between two word lines WL, which are adjacent to each other in the vertical direction Z and between the end portions of two semiconductor patterns 120, which are adjacent to each other in the vertical direction Z.

In some embodiments, a portion of the word line WL may be removed to form a word line pad WLP (refer FIG. 5). Word line pads WLP may be located in a staircase form. For example, a word line pad WLP connected to one word line WL may be apart from a word line pad WLP connected to another word line WL located under the one word line WL in the second lateral direction Y.

Thereafter, a mold insulating layer 122 may be formed to fill the inside of the second opening OP2. In some embodiments, the mold insulating layer 122 may be located between two word lines WL, which are adjacent to each other in the vertical direction Z, and between the end portions of two semiconductor patterns 120, which are adjacent to each other in the vertical direction Z.

The processes described above with reference to FIGS. 12, 13, 14A, and 14B may be performed to form the first stack structure SS1 shown in FIGS. 15 and 16, and the second stack structure SS2 may be placed on the first stack structure SS1.

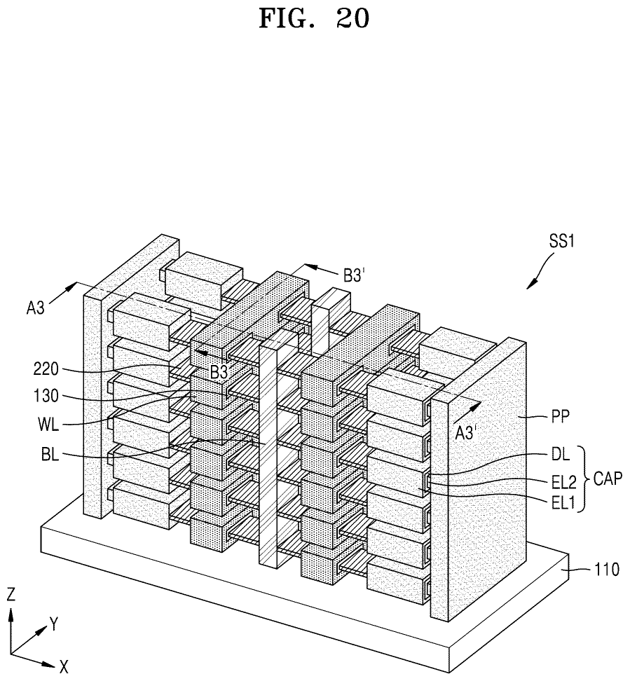

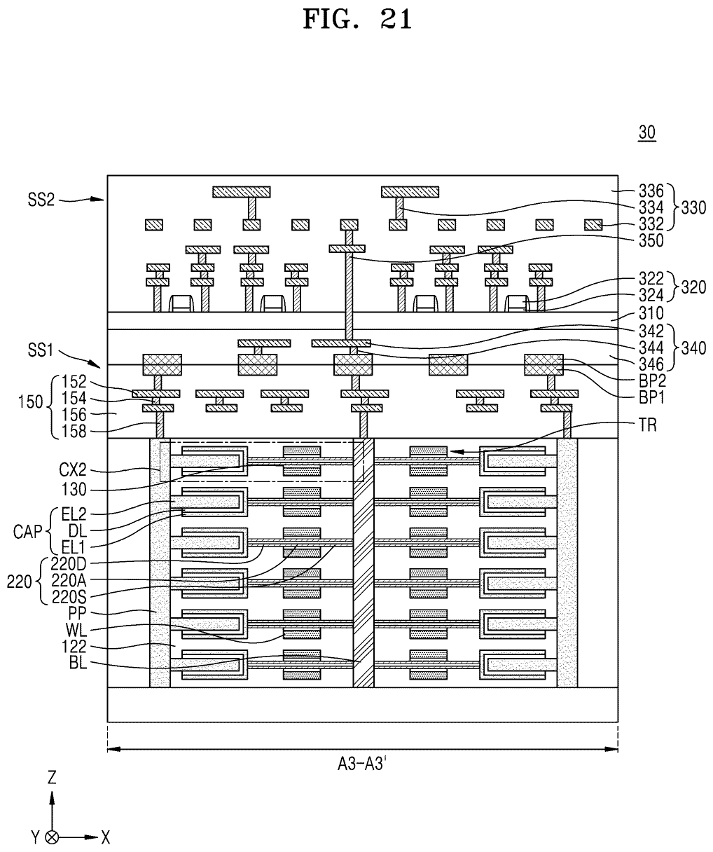

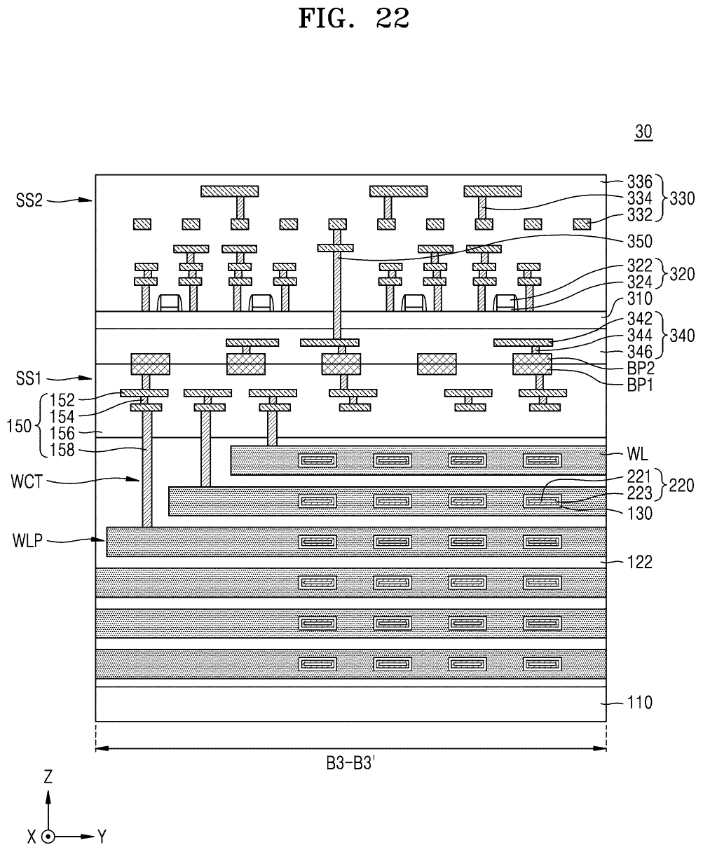

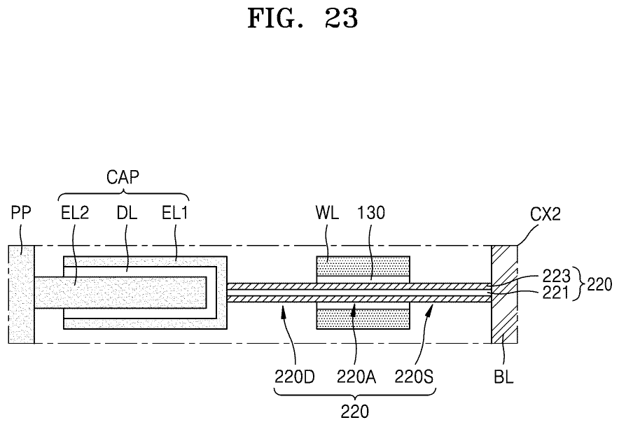

FIG. 20 is a perspective view of a memory cell array of a semiconductor memory device according to embodiments. FIG. 21 is a cross-sectional view taken along line A3-A3′ of FIG. 20. FIG. 22 is a cross-sectional view taken along line B3-B3′ of FIG. 20. FIG. 23 is an enlarged view of portion CX2 of FIG. 21.

Referring to FIGS. 20 to 23, a plurality of first semiconductor patterns 220 may extend in a first lateral direction X on a first substrate 110 and be apart from each other in a vertical direction Z. In some embodiments, each of the plurality of first semiconductor patterns 220 may include a seed layer 221 and an epitaxial layer 223. The epitaxial layer 223 may conformally surround the seed layer 221. The epitaxial layer 223 may surround the seed layer 221 and extend in a first lateral direction X.

In some embodiments, the seed layer 221 may include an undoped semiconductor material or a doped semiconductor material. In some embodiments, a plurality of semiconductor patterns 120 may include polysilicon. In some embodiments, the plurality of semiconductor patterns 120 may include an amorphous metal oxide, a polycrystalline metal oxide, or a combination thereof, for example, at least one of IGO, IZO, and IGZO. In some other embodiments, the plurality of semiconductor patterns 120 may include a 2D material semiconductor. For example, the 2D material semiconductor may include MoS₂, WSe₂, graphene, carbon nanotube, or a combination thereof.

In some embodiments, the epitaxial layer 223 may include SiGe. The epitaxial layer 223 may be formed by using an epitaxy process to surround the seed layer 221. In the processes described above with reference to FIGS. 8A, 8B, 9A, and 9B, the epitaxial layer 223 may be arranged by using the epitaxy process to surround the seed layer 221, and thus, a first semiconductor pattern 220 may be formed. Thereafter, the processes described above with reference to FIGS. 10A, 10B, 11A, 11B, 12, 13, 14A, and 14B may be performed to form the first stack structure SS1 shown in FIGS. 20 to 22, and the second stack structure SS2 may be formed on the first stack structure SS1.

In some embodiments, each of the plurality of first semiconductor patterns 220 may have a line shape or bar shape extending in the first lateral direction X. In some embodiments, each of first semiconductor patterns 220 may include a channel region 220A, a first impurity region 220S, and a second impurity region 220D. The first impurity region 220S and the second impurity region 220D may be arranged in the first lateral direction X with the channel region 220A therebetween. The first impurity region 220S may be connected to a bit line BL, and the second impurity region 220D may be connected to the cell capacitor CAP. An ohmic metal layer including a metal silicide may be further formed between the first impurity region 220S and the bit line BL and between the second impurity region 220D and the cell capacitor CAP.

In some embodiments, a plurality of word lines WL may surround the plurality of semiconductor patterns 120, extend in a second lateral direction Y, and be apart from each other in the vertical direction Z. One of the word lines WL may surround the plurality of semiconductor patterns 120, which are apart from each other in the second lateral direction Y, and extend in the second lateral direction Y.

In addition, as described above with reference to FIGS. 15 to 19, each of the plurality of word lines WL may include a first word line WL1 and a second word line WL2. A plurality of first word lines WL1 may surround the plurality of semiconductor patterns 120. The plurality of first word lines WL1 may extend in the second lateral direction Y and be apart from each other in the vertical direction Z. In this case, the first word line WL1 and the second word line WL2 may include materials having different work functions. For example, a work function of the second word line WL2 may be larger than a work function of the first word line WL1.

In some embodiments, the first impurity region 220S and the second impurity region 220D may have P-type conductivity. For example, the first impurity region 220S and the second impurity region 220D may include P-type impurities, such as boron (B), gallium (Ga), or aluminum (Al). For instance, the first impurity region 220S and the second impurity region 220D in the seed layer 221 may include SiGe doped with P-type impurities or silicon (Si) doped with P-type impurities. In addition, the first impurity region 220S and the second impurity region 220D in the epitaxial layer 223 may include a SiGe epitaxial layer doped with P-type impurities.

In some embodiments, the first impurity region 220S and the second impurity region 220D may have P-type conductivity, and thus, a cell transistor TR of a semiconductor memory device 30 according to the inventive concept may form a pFET. When the cell transistor TR forms the pFET, a floating body effect of the semiconductor memory device may be suppressed.

In some embodiments, by forming the epitaxial layer 223 including SiGe to surround the seed layer 221, characteristics of the semiconductor memory device may be improved through junction stress engineering. Specifically, by improving the mobility of holes, an on-current of the pFET may be improved to enhance electrical properties of the semiconductor memory device.

While the inventive concept has been particularly shown and described with reference to embodiments thereof, it will be understood that various changes in form and details may be made therein without departing from the spirit and scope of the following claims.

What is claimed is:

1. A semiconductor memory device comprising:
a first substrate;
semiconductor patterns extending in a first lateral direction on the first substrate, the semiconductor patterns being apart from each other in a second lateral direction and a vertical direction, each semiconductor pattern comprising a channel region, a first impurity region, and a second impurity region, and the first impurity region and the second impurity region being arranged in the first lateral direction with the channel region therebetween, wherein the second lateral direction intersects with the first lateral direction;
a word line surrounding the semiconductor pattern and extending in the second lateral direction;
a bit line electrically connected to the first impurity region of the semiconductor pattern, the bit line extending in the vertical direction; and
a cell capacitor electrically connected to the second impurity region of the semiconductor pattern; and
wherein the first impurity region and the second impurity region of the semiconductor pattern have P-type conductivity.

2. The device of claim 1, wherein the word line comprises:
a first word line surrounding a central portion of the channel region and extending in the second lateral direction; and
a pair of second word lines apart from each other with the first word line therebetween in the first lateral direction, the pair of second word lines extending in the second lateral direction.

3. The device of claim 2, wherein the first word line comprises a first material having a first work function; and wherein the second word line comprises a second material having a second work function, wherein the second work function is different from the first work function.

4. The device of claim 3, wherein the second work function is greater than the first work function.

5. The device of claim 2, wherein the pair of second word lines has the same width in the first lateral direction.

6. The device of claim 1, wherein the semiconductor pattern comprises:
a seed layer comprising a semiconductor material, the seed layer extending in the first lateral direction; and
an epitaxial layer surrounding the seed layer and extending in the first lateral direction.

7. The device of claim 6, wherein the first impurity region and the second impurity region in the seed layer comprise silicon germanium (SiGe) doped with P-type impurities or silicon (Si) doped with P-type impurities.

8. The device of claim 6, wherein the first impurity region and the second impurity region in the epitaxial layer comprises a silicon germanium (SiGe) epitaxial layer doped with P-type impurities.

9. The device of claim 1, wherein the cell capacitor comprises a first electrode, a capacitor dielectric layer, and a second electrode; and wherein the first electrode is electrically connected to the second impurity region of the semiconductor pattern, the first electrode comprising an inner space extending in the first lateral direction.

10. The device of claim 1, further comprising a gate insulating layer extending between the semiconductor pattern and the word line, the gate insulating layer conformally surrounding the channel region.

11. A semiconductor memory device comprising:
a first substrate;
semiconductor patterns extending in a first lateral direction on the first substrate, the semiconductor patterns being apart from each other in a second lateral direction and a vertical direction, each semiconductor pattern comprising a channel region, a first impurity region, and a second impurity region, and the first impurity region and the second impurity region being arranged in the first lateral direction with the channel region therebetween, wherein the second lateral direction intersects with the first lateral direction;
a word line surrounding the semiconductor pattern and extending in the second lateral direction;
a bit line electrically connected to the first impurity region of the semiconductor pattern, the bit line extending in the vertical direction; and
a cell capacitor electrically connected to the second impurity region of the semiconductor pattern;
wherein the semiconductor pattern comprises:
a seed layer extending in the first lateral direction; and
an epitaxial layer surrounding the seed layer and extending in the first lateral direction;
wherein the first impurity region and the second impurity region in the seed layer comprise silicon germanium (SiGe) doped with P-type impurities or silicon (Si) doped with P-type impurities; and
wherein the first impurity region and the second impurity region in the epitaxial layer comprise a SiGe epitaxial layer doped with P-type impurities.

12. The device of claim 11, wherein the word line comprises:
a first word line surrounding a central portion of the channel region and extending in the second lateral direction; and
a pair of second word lines apart from each other with the first word line therebetween in the first lateral direction, the pair of second word lines extending in the second lateral direction.

13. The device of claim 12, wherein the first word line comprises a first material having a first work function; and wherein the second word line comprises a second material having a second work function, wherein the second work function is different from the first work function.

14. The device of claim 13, wherein the second work function is greater than the first work function.

15. The device of claim 11, wherein the cell capacitor comprises a first electrode, a capacitor dielectric layer, and a second electrode; and wherein the first electrode is electrically connected to the second impurity region of the semiconductor pattern and comprises an inner space extending in the first lateral direction.

16. A semiconductor memory device comprising:
a first stack structure comprising a memory cell area, the memory cell area comprising a plurality of memory cells and a plurality of cell capacitors, which are arranged three-dimensionally; and
a second stack structure on the first stack structure, the second stack structure comprising a peripheral circuit area vertically overlapping the plurality of memory cells, and the peripheral circuit area being electrically connected to the plurality of memory cells,
wherein the first stack structure comprises:
a first substrate;
semiconductor patterns extending in a first lateral direction on the first substrate, the semiconductor patterns being apart from each other in a second lateral direction and a vertical direction, each semiconductor pattern comprising a channel region, a first impurity region, and a second impurity region, and the first impurity region and the second impurity region being arranged in the first lateral direction with the channel region therebetween, wherein the second lateral direction intersects with the first lateral direction;
a word line surrounding the semiconductor pattern and extending in the second lateral direction;
a bit line electrically connected to the first impurity region of the semiconductor pattern, the bit line extending in the vertical direction; and
a cell capacitor electrically connected to the second impurity region of the semiconductor pattern; and
wherein the first impurity region and the second impurity region of the semiconductor pattern have P-type conductivity.

17. The device of claim 16, wherein the word line comprises:
a first word line surrounding a central portion of the channel region and extending in the second lateral direction, the first word line comprising a first material having a first work function; and
a pair of second word lines apart from each other with the first word line therebetween in the first lateral direction, the pair of second word lines extending in the second lateral direction; and
wherein the pair of second word lines comprise a second material having a second work function, wherein the second work function is different from the first work function.

18. The device of claim 17, wherein the second work function is greater than the first work function.

19. The device of claim 16, wherein the semiconductor pattern comprises:
a seed layer comprising a semiconductor material, the seed layer extending in the first lateral direction; and
an epitaxial layer surrounding the seed layer and extending in the first lateral direction.

20. The device of claim 19, wherein the first impurity region and the second impurity region in the seed layer comprise silicon germanium (SiGe) doped with P-type impurities or silicon (Si) doped with P-type impurities; and
wherein the first impurity region and the second impurity region in the epitaxial layer comprise a SiGe epitaxial layer doped with P-type impurities.
